(19) United States
(12) Patent Application Publication
(10) Pub. No.: US 2025/0349328 A1
(43) Pub. Date: Nov. 13, 2025

(54) INTEGRATED CIRCUIT DEVICE HAVING SWING DETECTOR AND SYSTEM INCLUDING INTEGRATED CIRCUIT DEVICES

(71) Applicant: SK hynix Inc., Gyeonggi-do (KR)

(72) Inventors: Hyung Rok DO, Gyeonggi-do (KR); Kyu Dong HWANG, Gyeonggi-do (KR)

(21) Appl. No.: 18/795,185

(22) Filed: Aug. 6, 2024

(30) Foreign Application Priority Data
May 7, 2024 (KR) 10-2024-0059708

(51) Int. Cl. G11C 7/10; G11C 7/22; H03K 19/0185

(52) U.S. Cl. CPC G11C 7/10; G11C 7/222; H03K 19/018528

(57) ABSTRACT

Disclosed is a system including a first integrated circuit device and a second integrated circuit device coupled to the first integrated through a first transmission line and a second transmission line, wherein the first integrated circuit device includes a swing detector configured to detect a voltage level difference between the first transmission line and the second transmission line, a comparator configured to compare a detection value of the swing detector with a reference swing value, and a comparison result transmission circuit configured to transmit a comparison result of the comparator to the second integrated circuit device.

### CROSS-REFERENCE TO RELATED APPLICATION(S)

This application claims priority under 35 U.S.C. § 119 to Korean Patent Application No. 10-2024-0059708, filed on May 7, 2024, the disclosure of which is incorporated herein by reference in its entirety.

### BACKGROUND

### 1. Technical Field

Various embodiments of the present disclosure relate to integrated circuit devices, and more particularly, to transmission and receiving of a high-speed signal between integrated circuit devices.

### 2. Related Art

In response to a demand for low power consumption and a high-speed operation of memory, commands and addresses are received in synchronization with a low-speed main clock, and data is received in synchronization with a high-speed data clock. Using the low-speed main clock makes it possible to reduce the amount of current required to receive the commands and addresses, and using the high-speed data clock makes it possible to receive data at a high speed.

In general, a data clock is activated and toggles only during a period where the data clock needs to be used and is deactivated during the other periods where the data clock does not need to be used, in order to reduce current consumption. During a period where a state of the data clock changes from a deactivation state to an activation state, it is difficult to rightly receive the data clock due to effects such as inter symbol interference (ISI). This interference typically occurs in high-speed communication systems, where the symbols are transmitted so closely together in time that the tail end of one symbol overlaps with the beginning of the next.

### SUMMARY

In accordance with an embodiment of the present disclosure, a system may include: a first integrated circuit device; and a second integrated circuit device coupled to the first integrated through a first transmission line and a second transmission line, wherein the first integrated circuit device includes a swing detector configured to detect a voltage level difference between the first transmission line and the second transmission line; a comparator configured to compare a detection value of the swing detector with a reference swing value; and a comparison result transmission circuit configured to transmit a comparison result of the comparator to the second integrated circuit device.

In accordance with an embodiment of the present disclosure, an integrated circuit device may include a swing detector configured to detect a voltage level difference between a first transmission line and a second transmission line; a comparator configured to compare a detection value of the swing detector with a reference swing value; and a comparison result transmission circuit configured to transmit a comparison result of the comparator.

In accordance with an embodiment of the present disclosure, an integrated circuit device may include a differential transmission circuit configured to transmit a differential signal through a first transmission line and a second transmission line; a receiving circuit configured to receive pre-level driving intensity information from a device that receives the differential signal; and a pre-level driving circuit configured to perform pre-level driving to reduce a voltage difference between the first transmission line and the second transmission line, and adjust an intensity of the pre-level driving according to the pre-level driving intensity information.

### BRIEF DESCRIPTION OF THE DRAWINGS

FIG. 1 is a block diagram illustrating a configuration of a memory system in accordance with an embodiment of the present disclosure.

FIG. 2 is a timing diagram for describing an operation of a memory system illustrated in FIG. 1.

FIG. 3 is a block diagram illustrating a configuration of a memory system in accordance with an embodiment of the present disclosure.

FIG. 4 is a block diagram illustrating an embodiment of a time control circuit illustrated in FIG. 3.

FIG. 5 is a timing diagram for describing an operation of a memory controller illustrated in FIG. 3.

FIG. 6 is a block diagram illustrating a configuration of a memory system in accordance with an embodiment of the present disclosure.

FIG. 7 is a diagram illustrating an embodiment of a reference voltage generator illustrated in FIG. 6.

FIG. 8 is a block diagram illustrating an embodiment of a swing detector illustrated in FIG. 6.

FIG. 9 is a block diagram illustrating another embodiment of a swing detector illustrated in FIG. 6.

FIG. 10 is a block diagram illustrating an embodiment of a pre-level driving circuit illustrated in FIG. 6.

FIG. 11 is a block diagram illustrating another embodiment of a pre-level driving circuit illustrated in FIG. 6.

### DETAILED DESCRIPTION

Various embodiments of the present disclosure are directed to technology capable of stably receiving a high-speed differential signal.

According to embodiments of the present disclosure, it is possible to stably receive a high-speed differential signal.

Hereinafter, various embodiments according to the technical spirit of the present disclosure are described below with reference to the accompanying drawings.

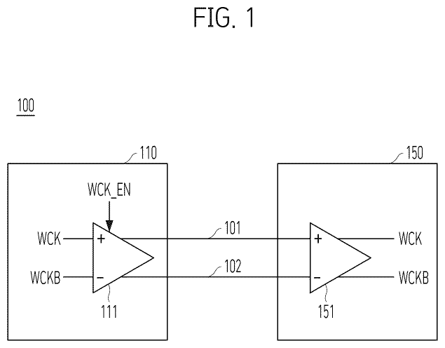

FIG. 1 is a block diagram illustrating a configuration of a memory system 100 in accordance with an embodiment of the present disclosure. FIG. 1 only illustrates configurations directly related to transmission of data clocks WCK and WCKB in the memory system 100.

Referring to FIG. 1, the memory system 100 may include a memory controller 110 and a memory 150. The memory controller 110 may control read and write operations of the memory 150 at a request of a host, and the memory 150 may perform the read and write operations under the control of the memory controller 110.

The data clocks WCK and WCKB are clocks supplied from the memory controller 110 to the memory 150. Accordingly, the memory controller 110 may include a differential transmission circuit 111 that transmits the data clocks WCK and WCKB, and the memory 150 may include a differential receiving circuit 151 that receives the data clocks WCK and WCKB.

The differential transmission circuit 111 of the memory controller 110 may transmit the data clocks WCK and WCKB through a first transmission line 101 and a second transmission line 102. Because the data clocks WCK and WCKB are differential signals, the data clocks WCK and WCKB include a primary data clock signal WCK and a secondary data clock signal WCKB. The differential transmission circuit 111 may transmit the primary data clock signal WCK through the first transmission line 101 and the secondary data clock signal WCKB through the second transmission line 102.

The data clocks WCK and WCKB are clocks used to transmit data, but data is not transmitted in the memory system 100 at all times. Accordingly, the differential transmission circuit 111 may be deactivated (i.e., disabled) during a period where data is not transmitted, that is, during a period where the data clocks WCK and WCKB are not needed. A transmission activation signal WCK_EN may be a signal that activates or deactivates the differential transmission circuit 111. When the transmission activation signal WCK_EN is activated, the differential transmission circuit 111 may be activated (i.e., enabled) and transmit the data clocks WCK and WCKN through the first transmission line 101 and the second transmission line 102. When the transmission activation signal WCK_EN is deactivated, the differential transmission circuit 111 may be deactivated. Hence, the differential transmission circuit 111 may fix a voltage level of the first transmission line 101 at a low level and a voltage level of the second transmission line 102 at a high level, thereby preventing current consumption.

The differential receiving circuit 151 of the memory 150 may receive the data clocks WCK and WCKB transmitted from the memory controller 110 through the first transmission line 101 and the second transmission line 102. The data clocks WCK and WCKB received by the differential receiving circuit 151 may be used by the memory 150 to receive data.

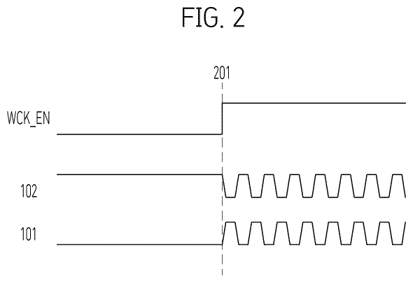

FIG. 2 is a timing diagram for describing an operation of the memory system 100 illustrated in FIG. 1.

Referring to FIG. 2, while the transmission activation signal WCK_EN is deactivated at a low level, the voltage level of the first transmission line 101 may be fixed at a low level, and the voltage level of the second transmission line 102 may be fixed at a high level.

When the transmission activation signal WCK_EN is activated at a high level at a point in time 201, the primary data clock signal WCK may be transmitted through the first transmission line 101, and the secondary data clock signal WCKB having a phase opposite to that of the primary data clock signal WCK may be transmitted through the second transmission line 102.

Before the point in time 201, the voltage level of the first transmission line 101 is fixed at a low level, and the voltage level of the second transmission line 102 is fixed at a high level. When the first and second transmission lines 101 and 102 start to toggle at a high speed from the point in time 201, the memory 150, which is a receiving end, may have difficulty in receiving the data clocks WCK and WCKB transmitted through the transmission lines 101 and 102 due to inter symbol interference (ISI) caused by reflection and distortion of signals transmitted through the transmission lines 101 and 102.

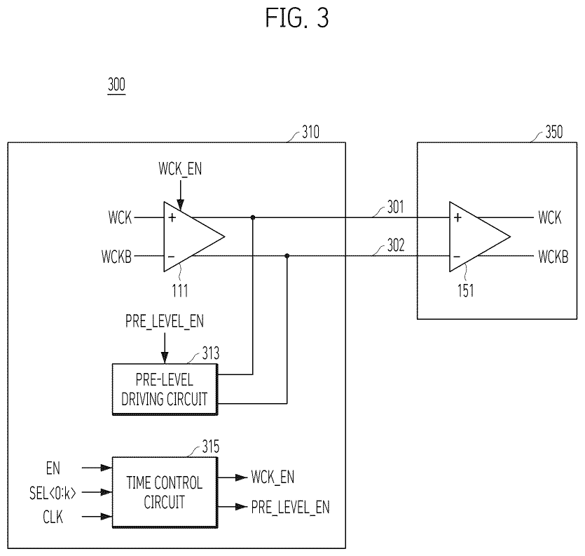

FIG. 3 is a block diagram illustrating a configuration of a memory system 300 in accordance with an embodiment of the present disclosure. FIG. 3 only illustrates configurations directly related to transmission of the data clocks WCK and WCKB.

Referring to FIG. 3, the memory system 300 may include a memory controller 310 and a memory 350.

The memory controller 310 may include a differential transmission circuit 111, a pre-level driving circuit 313, and a time control circuit 315. The memory 350 may include a differential receiving circuit 151.

The pre-level driving circuit 313 may perform pre-level driving on a first transmission line 301 and a second transmission line 302. The pre-level driving may reduce a voltage difference between the first transmission line 301 and the second transmission line 302 before the differential transmission circuit 111 is activated. The pre-level driving circuit 313 may be activated based on a pre-level driving activation signal PRE-LEVEL_EN and perform the pre-level driving to increase a voltage level of the first transmission line 301 and lower a voltage level of the second transmission line 302 during the activation.

The time control circuit 315 may adjust a pre-level driving time of the pre-level driving circuit 313. Before the differential transmission circuit 111 is activated, the pre-level driving circuit 313 is activated for a predetermined time. In this case, the time control circuit 315 may use the pre-level driving activation signal PRE-LEVEL_EN and adjust a length of the predetermined time. The time control circuit 315 may generate a transmission activation signal WCK_EN. An activation signal EN inputted to the time control circuit 315 may be a source signal for generating the transmission activation signal WCK_EN, and selection signals SEL<0:k> may be signals for adjusting a length of an activation period of the pre-level driving activation signal PRE-LEVEL_EN. In addition, a clock CLK inputted to the time control circuit 315 may be a clock used to transmit and receive commands and addresses between the memory controller 310 and the memory 350.

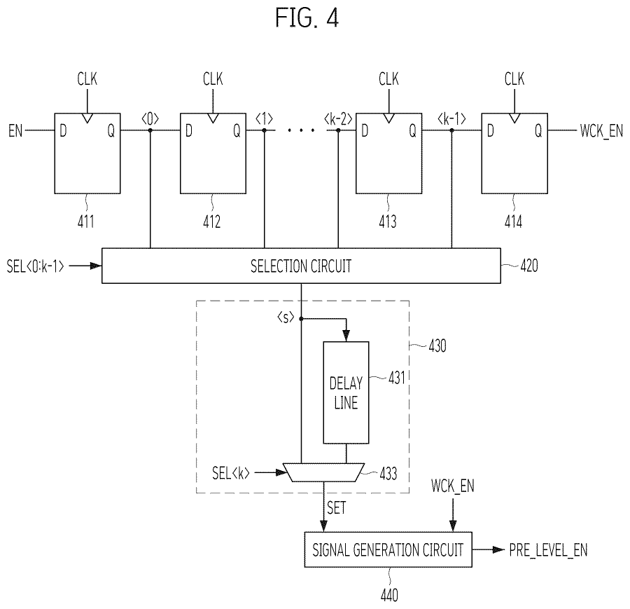

FIG. 4 is a block diagram illustrating an embodiment of the time control circuit 315 illustrated in FIG. 3.

Referring to FIG. 4, the time control circuit 315 may include a plurality of shift circuits 411 to 414, a selection circuit 420, a delay circuit 430, and a signal generation circuit 440.

The plurality of shift circuits 411 to 414 may shift the activation signal EN in synchronization with the clock CLK and generate the transmission activation signal WCK_EN. Each of the plurality of shift circuits 411 to 414 may be a D flip-flop.

The selection circuit 420 may select one of output signals <0> to <k-1> of the shift circuits 411 to 413 in response to the selection signals SEL<0:k-1>.

The delay circuit 430 may add an async delay value to a signal <S> selected by the selection circuit 420. The delay circuit 430 may include a delay line 431 and a selector 433. The delay line 431 may delay the selected signal <S> and output a delayed signal, and the selector 433 may select one of the outputted signal of the delay line 431 and the selected signal <S> according to a level of a selection signal SEL<k> and output a selected signal. Depending on whether the selector 433 selects the outputted signal of the delay line 431 or the bypassed signal <S>, the async delay value may or may not be added to the selected signal <S>. Because the delay circuit 430 is for fine adjustment of the async delay value, a delay value of the delay line 431 may be shorter than one cycle of the clock CLK.

The signal generation circuit 440 may activate the pre-level driving activation signal PRE-LEVEL_EN in response to activation of an output signal SET of the delay circuit 430 and deactivate the pre-level driving activation signal PRE-LEVEL_EN in response to activation of the transmission activation signal WCK_EN. Accordingly, the pre-level driving activation signal PRE-LEVEL_EN may be activated earlier than the transmission activation signal WCK_EN and be deactivated during the activation of the transmission activation signal WCK_EN. The length of the activation period of the pre-level driving activation signal PRE-LEVEL_EN may be a value obtained by subtracting activation time of the selected signal <S> from activation time of the transmission activation signal WCK_EN and then adding the delay value of the delay circuit 430.

The delay circuit 430, which is to finely adjust the activation period of the pre-level driving activation signal PRE-LEVEL_EN, may be omitted from the time control circuit 315 when it does not need to finely adjust the activation period of the pre-level driving activation signal PRE-LEVEL_EN. The signal <S> selected by the selection circuit 420 may be directly inputted to the signal generation circuit 440.

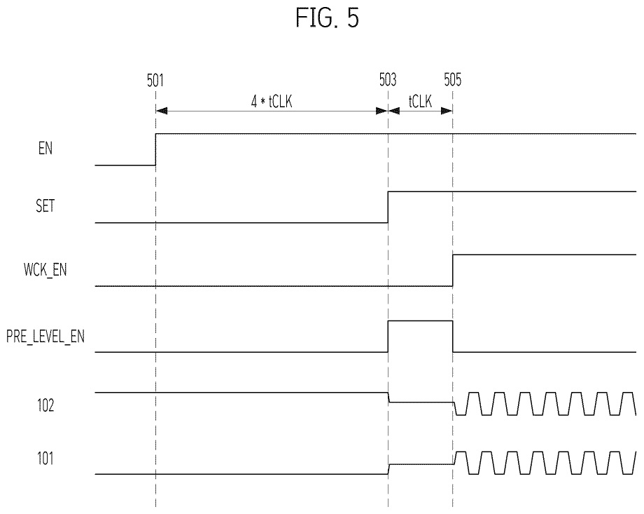

FIG. 5 is a timing diagram for describing an operation of the memory controller 310 illustrated in FIG. 3.

Hereinafter, for convenience in description, the number of the shift circuits 411 to 414 of FIG. 4 is five, the selection circuit 420 selects an output signal <3> of the shift circuit 413, and the selector 433 of the delay circuit 430 selects the bypassed signal <S>.

Referring to FIG. 5, it may be seen that the output signal SET of the delay circuit 430 is activated at a point in time 503, which is after four clocks 4*tCLK elapse from activation point in time 501 of the activation signal EN, and the pre-level driving activation signal PRE-LEVEL_EN is activated in response to the output signal SET. In addition, it may be seen that the transmission activation signal WCK_EN is activated at a point in time 505, which is after five clocks 5*tCLK elapse from the activation point in time 501 of the activation signal EN, and the pre-level driving activation signal PRE-LEVEL_EN is deactivated in response to the transmission activation signal WCK_EN. The pre-level driving activation signal PRE-LEVEL_EN may be activated during one clock period before the activation of the transmission activation signal WCK_EN.

While the transmission activation signal WCK_EN is deactivated, the voltage level of the first transmission line 301 may be fixed at a level of a ground voltage VSS by the differential transmission circuit 111, and the voltage level of the second transmission line 302 may be fixed at a level of a power source voltage VDD by the differential transmission circuit 111.

During a time period between the point in time 503 at which the pre-level driving activation signal PRE-LEVEL_EN is activated and the point in time 505, the first and second transmission lines 301 and 302 may be pre-level driven by the pre-level driving circuit 313. The pre-level driving circuit 313 may increase the voltage level of the first transmission line 301 and lower the voltage level of the second transmission line 302, thereby reducing the voltage difference between the first transmission line 301 and the second transmission line 302.

The transmission activation signal WCK_EN may be activated from the point in time 505 after the pre-level driving, and the data clocks WCK and WCKB may be transmitted at a high speed through the first and second transmission lines 301 and 302. Because the data clocks WCK and WCKB start to be transmitted after the voltage difference between the first transmission line 301 and the second transmission line 302 is reduced through the pre-level driving, inter symbol interference (ISI) caused by reflection and distortion of signals may be reduced, and the memory 350, which is a receiving end, may more stably receive the data clocks WCK and WCKB transmitted through the transmission lines 301 and 302.

As described above, a length of a pre-level driving period may be adjusted by the time control circuit 315. It may be advantageous to increase the length of the pre-level driving period as frequencies of the data clocks WCK and WCKB increase and to reduce the length of the pre-level driving period as the frequencies of the data clocks WCK and WCKB decrease.

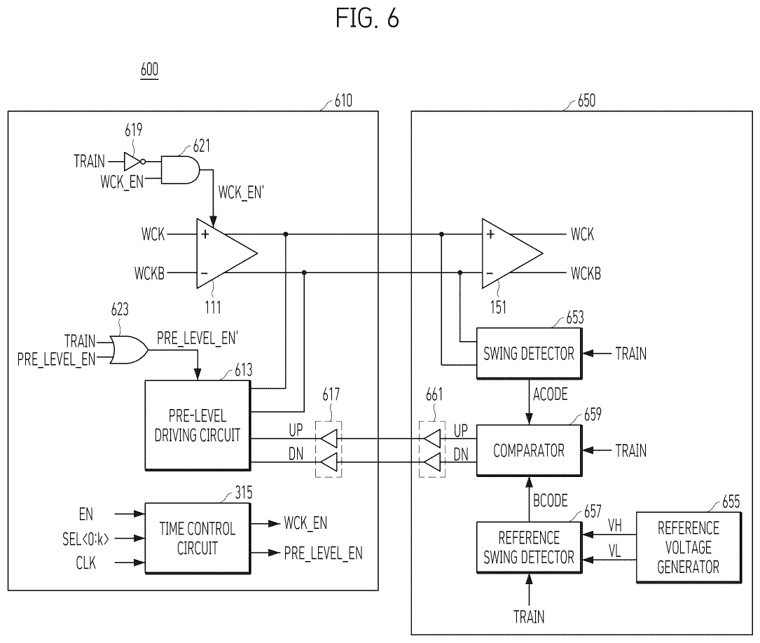

FIG. 6 is a block diagram illustrating a configuration of a memory system 600 in accordance with an embodiment of the present disclosure. The memory system 600 of FIG. 6 may further include configurations for a training operation of adjusting an intensity of pre-level driving, differently from the memory system 300 of FIG. 3.

Referring to FIG. 6, a memory controller 610 may include a differential transmission circuit 111, a pre-level driving circuit 613, a time control circuit 315, and a receiving circuit 617.

A training signal TRAIN is a signal activated during the training operation of adjusting the intensity of the pre-level driving. When the training signal TRAIN is activated, a transmission activation signal WCK_EN′ inputted to the differential transmission circuit 111 by an inverter 619 and an AND gate 621 may be deactivated, a pre-level driving activation signal PRE-LEVEL_EN′ inputted to the pre-level driving circuit 613 by an OR gate 623 may be activated. During the training operation, the differential transmission circuit 111 may be deactivated, and the pre-level driving circuit 613 may be activated.

The receiving circuit 617 may receive an up signal UP and a down signal DN, which are pre-level driving intensity information transmitted from a memory 650, and the pre-level driving circuit 613 may adjust the intensity of the pre-level driving in response to the up signal UP and the down signal DN. The pre-level driving circuit 613 may adjust the intensity of the pre-level driving to be higher when the up signal UP is activated and adjust the intensity of the pre-level driving to be lower when the down signal DN is activated.

The memory 650 may include a differential receiving circuit 151, a swing detector 653, a reference voltage generator 655, a reference swing detector 657, a comparator 659, and a comparison result transmission circuit 661.

The swing detector 653 may detect a voltage difference between a first transmission line 601 and a second transmission line 602 during the training operation during which the training signal TRAIN is activated. The swing detector 653 may detect the voltage difference between the first transmission line 601 and the second transmission line 602 during the pre-level driving. A detection result ACODE of the swing detector 653 may be generated in the form of a digital code.

The reference voltage generator 655 may generate a low reference voltage VL, which is a target voltage value of the first transmission line 601, and a high reference voltage VH, which is a target voltage value of the second transmission line 602, during the pre-level driving.

The reference swing detector 657 may detect a voltage difference between the low reference voltage VL and the high reference voltage VH and generate a detection result BCODE in the form of a digital code, during the training operation during which the training signal TRAIN is activated.

The comparator 659 may compare the detection result ACODE of the swing detector 653 with the detection result BCODE of the reference swing detector 657 and generate the up signal UP and the down signal DN, during the training operation during which the training signal TRAIN is activated. When the detection result ACODE is greater than the detection result BCODE, that is, when the voltage difference between the first transmission line 601 and the second transmission line 602 is greater than the voltage difference between the high reference voltage VH and the low reference voltage VL, the up signal UP may be activated because the intensity of the pre-level driving needs to increase, in order to reduce the voltage difference. In a contrary case, that is, when the detection result BCODE is greater than the detection result ACODE, that is, when the voltage difference between the first transmission line 601 and the second transmission line 602 is smaller than the voltage difference between the high reference voltage VH and the low reference voltage VL, the down signal DN may be activated.

The comparison result transmission circuit 661 may transmit the up signal UP and the down signal DN, which are generated by the comparator 659, to the memory 650.

During the training operation, the differential transmission circuit 111 of the memory controller 610 is deactivated, and the pre-level driving circuit 613 is activated. Accordingly, the first and second transmission lines 601 and 602 may be pre-level driven. The swing detector 653 of the memory 650 detects the voltage difference between the first transmission line 601 and the second transmission line 602, and the comparator 659 compares a value generated by the swing detector 653, i.e., ACODE, with a reference value, i.e., BCODE. The memory 650 may transmit the up and down signals UP and DN generated according to the comparison result to the memory controller 610, and the pre-level driving circuit 613 of the memory controller 610 may adjust the intensity of the pre-level driving to be higher or lower in response to the up and down signals UP and DN. Consequently, during the pre-level driving, the voltage difference between the first transmission line 601 and the second transmission line 602 may be adjusted to have the same value as an ideal voltage difference. When the voltage difference between the first transmission line 601 and the second transmission line 602 is adjusted to the ideal voltage difference during the pre-level driving, the differential receiving circuit 151 of the memory 650 may more stably receive data clocks WCK and WCKB.

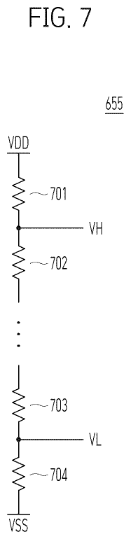

FIG. 7 is a diagram illustrating an embodiment of the reference voltage generator 655 illustrated in FIG. 6.

Referring to FIG. 7, the reference voltage generator 655 may include resistors 701, 702, 703, and 704 coupled to one another between a power source voltage terminal VDD and a ground voltage terminal VSS. The reference voltage generator 655 may generate the high reference voltage VH and the low reference voltage VL according to a voltage distribution of the resistors 701, 702, 703, and 704.

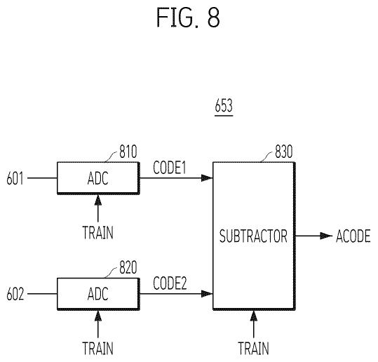

FIG. 8 is a block diagram illustrating an embodiment of the swing detector 653 illustrated in FIG. 6. The reference swing detector 657 may have the same configuration as the swing detector 653 illustrated in FIG. 8.

Referring to FIG. 8, the swing detector 653 may include a first analog-to-digital converter (ADC) 810, a second analog-to-digital converter 820, and a subtractor 830.

The first analog-to-digital converter 810 may convert a voltage level of the first transmission line 601 into a first digital code CODE1. In addition, the second analog-to-digital converter 820 may convert a voltage level of the second transmission line 602 into a second digital code CODE2.

The subtractor 830 may subtract a code value of the first digital code CODE1 from a code value of the second digital code CODE2 and generate the detection result ACODE. Consequently, the detection result ACODE may be a digital code corresponding to the difference between the voltage level of the first transmission line 601 and the voltage level of the second transmission line 602.

The first analog-to-digital converter 810, the second analog-to-digital converter 820, and the subtractor 830 may be activated and operate when the training signal TRAIN is activated and be deactivated when the training signal TRAIN is deactivated.

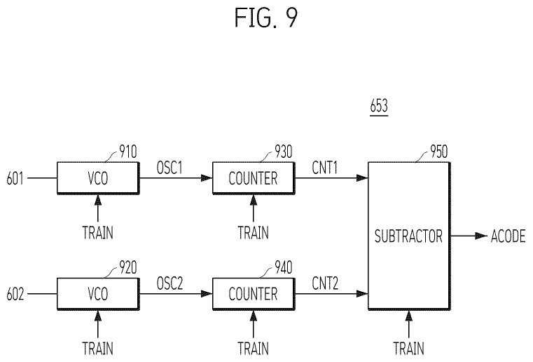

FIG. 9 is a block diagram illustrating another embodiment of the swing detector 653 illustrated in FIG. 6. The reference swing detector 657 may have the same configuration as the swing detector 653 illustrated in FIG. 9.

Referring to FIG. 9, the swing detector 653 may include a first oscillator 910, a second oscillator 920, a first counter 930, a second counter 940, and a subtractor 950.

The first oscillator 910 may generate a first periodic wave OSC1 corresponding to the voltage level of the first transmission line 601. The first oscillator 910 may be a voltage controlled oscillator (VCO), and as the voltage level of the first transmission line 601 increases, a frequency of the first periodic wave OSC1 increases.

The second oscillator 920 may generate a second periodic wave OSC2 corresponding to the voltage level of the second transmission line 602. The second oscillator 920 may be a voltage controlled oscillator, and as the voltage level of the second transmission line 602 increases, a frequency of the second periodic wave OSC2 increases.

The first counter 930 may count the number of activations of the first periodic wave OSC1 and generate a first counting value CNT1. As the voltage level of the first transmission line 601 increases, the frequency of the first periodic wave OSC1 increases, and therefore, the first counting value CNT1 may increase as the voltage level of the first transmission line 601 increases.

The second counter 940 may count the number of activations of the second periodic wave OSC2 and generate a second counting value CNT2. As the voltage level of the second transmission line 602 increases, the frequency of the second periodic wave OSC2 increases, and therefore, the second counting value CNT2 may increase as the voltage level of the second transmission line 602 increases.

The subtractor 950 may subtract the first counting value CNT1 from the second counting value CNT2 and generate the detection result ACODE. Consequently, the detection result ACODE may be a digital code corresponding to the difference between the voltage level of the first transmission line 601 and the voltage level of the second transmission line 602.

The first oscillator 910, the second oscillator 920, the first counter 930, the second counter 940, and the subtractor 950 may be activated and operate when the training signal TRAIN is activated and be deactivated when the training signal TRAIN is deactivated.

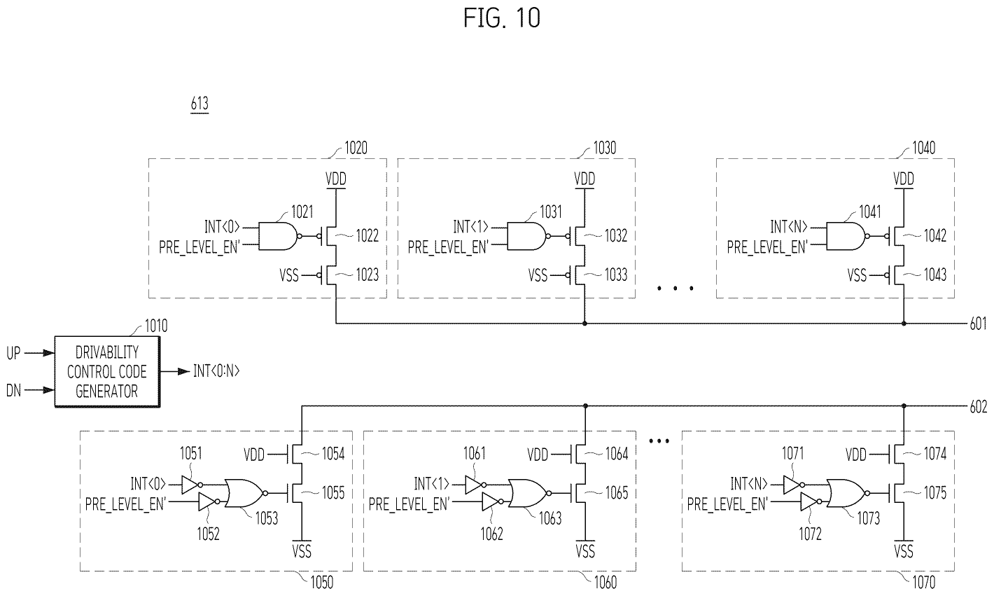

FIG. 10 is a block diagram illustrating an embodiment of the pre-level driving circuit 613 illustrated in FIG. 6.

Referring to FIG. 10, the pre-level driving circuit 613 may include a drivability control code generator 1010, pull-up drivers 1020, 1030, and 1040, and pull-down drivers 1050, 1060, and 1070.

The drivability control code generator 1010 may generate a drivability control code INT<0:N> in response to the up signal UP and the down signal DN. The drivability control code generator 1010 may increase the number of signals each having a high value among signals of the drivability control code INT<0:N> whenever the up signal UP is activated, and decrease the number of signals each having a high value among signals of the drivability control code INT<0:N> whenever the down signal DN is activated. For example, when two of the signals of the drivability control code INT<0:N> have a high value, three of the signals of the drivability control code INT<0:N> may have a high value once the up signal UP is activated.

The pull-up drivers 1020, 1030, and 1040 may perform pull-up driving to increase the voltage level of the first transmission line 601 during a period where the pre-level driving activation signal PRE-LEVEL_EN′ is activated. The number of activated drivers among the pull-up drivers 1020, 1030, and 1040 may be determined based on the drivability control code INT<0:N>. Among the pull-up drivers 1020, 1030, and 1040, pull-up drivers whose code signals are at a high level may be activated and perform the pull-up driving on the first transmission line 601 when the pre-level driving activation signal PRE_LEVEL_EN′ is activated. For example, when the code signal INT<0> is at a high level, and the code signal INT<1> is at a low level, the pull-up driver 1020 may be activated and perform the pull-up driving on the first transmission line 601, but the pull-up driver 1030 may be deactivated, when the pre-level driving activation signal PRE_LEVEL_EN′ is activated.

The pull-up drivers 1020, 1030, and 1040 may include corresponding NAND gates 1021, 1031, and 1041 that receive the code signals INT<0:N> and the pre-level driving activation signal PRE-LEVEL_EN′ and corresponding two PMOS transistors 1022, 1023, 1032, 1033, 1042, and 1043 connected in series to each other to perform the pull-up driving on the first transmission line 601. Because a ground voltage VSS is inputted to gates of the PMOS transistors 1023, 1033, and 1043, the PMOS transistors 1023, 1033, and 1043 may remain turned on at all times, and the PMOS transistors 1022, 1032, and 1042 may be turned on or off in response to output signals of the NAND gates 1021, 1031, and 1041. Because the pull-up drivers 1020, 1030, and 1040 are drivers that slightly increase the voltage level of the first transmission line 601 during the pre-level driving, the drivability may be designed to be weak.

The pull-down drivers 1050, 1060, and 1070 may perform pull-down driving to lower the voltage level of the second transmission line 602 during a period where the pre-level driving activation signal PRE-LEVEL_EN′ is activated. The number of activated drivers among the pull-down drivers 1050, 1060, and 1070 may be determined based on the drivability control code INT<0:N>. Among the pull-down drivers 1050, 1060, and 1070, pull-down drivers whose code signals are at a high level may be activated and perform the pull-down driving on the second transmission line 602 when the pre-level driving activation signal PRE_LEVEL_EN′ is activated. For example, when the code signal INT<0> is at a high level, and the code signal INT<1> is at a low level, the pull-down driver 1050 may be activated and perform the pull-down driving on the second transmission line 60, but the pull-down driver 1060 may be deactivated, when the pre-level driving activation signal PRE_LEVEL_EN′ is activated.

The pull-down drivers 1050, 1060, and 1070 may include corresponding inverters 1051, 1061, and 1071 that inverts the code signals INT<0:N>, corresponding inverters 1052, 1062, and 1072 that inverts the pre-level driving activation signal PRE_LEVEL_EN′, corresponding NOR gates 1053, 1063, and 1073 that receive output signals of the corresponding inverters 1051, 1061, 1071, 1052, 1062, and 1072, and corresponding two NMOS transistors 1054, 1055, 1064, 1065, 1074, and 1075 connected in series to each other to perform the pull-down driving on the second transmission line 602. Because a power source voltage VDD is inputted to gates of the NMOS transistors 1054, 1064, and 1074, the NMOS transistors 1054, 1064, and 1074 may remain turned on at all times, and the NMOS transistors 1055, 1065, and 1075 may be turned on or off in response to output signals of the NOR gates 1053, 1063, and 1073. Because the pull-down drivers 1050, 1060, and 1070 are drivers that slightly lower the voltage level of the second transmission line 602 during the pre-level driving, the drivability may be designed to be weak.

The drivability control code INT<0:N> in the form of a thermometer code is described as an example, but the drivability control code INT<0:N> may be in the form of a binary code. In this case, the drivability of the drivers 1020, 1030, 1040, 1050, 1060, and 1070 may be designed to have binary weight.

In FIG. 10, the transistors 1023, 1033, 1043, 1054, 1064, and 1074 remain turned on, and therefore, the transistors 1023, 1033, 1043, 1054, 1064, and 1074 may be omitted.

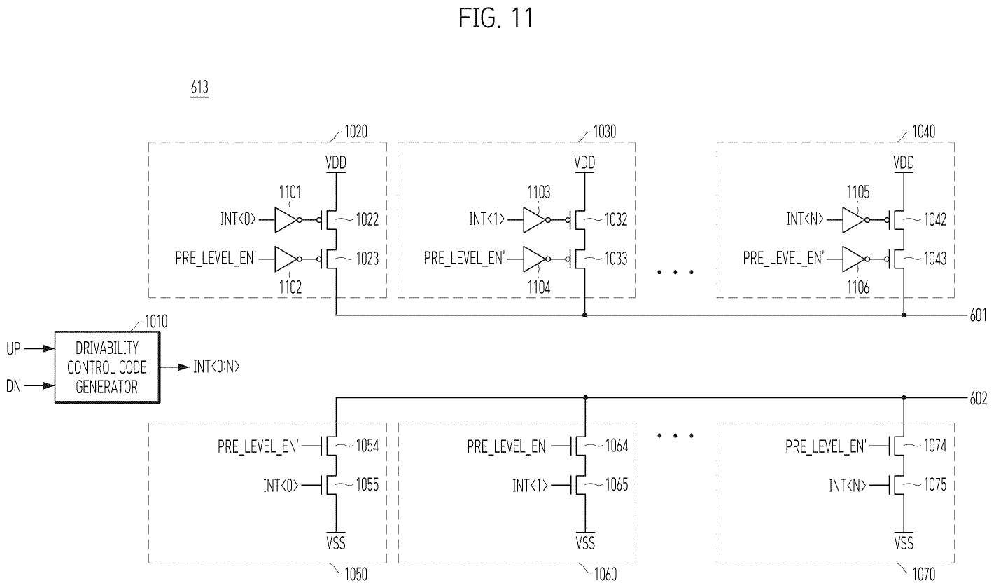

FIG. 11 is a block diagram illustrating another embodiment of the pre-level driving circuit 613 illustrated in FIG. 6.

Referring to FIG. 11, it may be seen that configurations of pull-up drivers 1020, 1030, and 1040 and pull-down drivers 1050, 1060, and 1070 are different from those illustrated in FIG. 10.

It may be seen that in the pull-up drivers 1020, 1030, and 1040, the pre-level driving activation signal PRE-LEVEL_EN′ inverted by inverters 1101, 1103, and 1105 is inputted to transistors 1022, 1032, and 1042 and a drivability control code INT<0:N> inverted by inverters 1102, 1104, and 1106 is inputted to respective transistors 1023, 1033, and 1043.

It may be seen that in the pull-down drivers 1050, 1060, and 1070, the pre-level driving activation signal PRE-LEVEL_EN′ is directly inputted to transistors 1054, 1064, and 1074 and the drivability control code INT<0:N> is directly inputted to corresponding transistors 1055, 1065, and 1075.

Detailed configurations of the pull-up drivers 1020, 1030, and 1040 and the pull-down drivers 1050, 1060, and 1070 are changed, and the pull-up drivers 1020, 1030, and 1040 and the pull-down drivers 1050, 1060, and 1070 may operate in the same manner as those illustrated in FIG. 10.

In the above-described embodiments, configurations for stably transmitting and receiving a data clock, which is a high-speed differential signal, between a memory controller and a memory have been described. It is apparent that these configurations may be used to stably transmit and receive any high-speed differential signal between not only the memory controller and the memory but also two different integrated circuit devices.

Although embodiments according to the technical spirit of the present disclosure have been described above with reference to the accompanying drawings, this is only for describing the embodiments according to the concept of the present disclosure, and the present disclosure is not limited to the above embodiments. Various types of substitutions, modifications, and changes for the embodiments may be made by those skilled in the art, to which the present disclosure pertains, without departing from the technical spirit of the present disclosure defined in the following claims, and it should be construed that these substitutions, modifications, and changes belong to the scope of the present disclosure. Furthermore, the embodiments may be combined to form additional embodiments.

What is claimed is:

1. A system comprising:
a first integrated circuit device; and
a second integrated circuit device coupled to the first integrated through a first transmission line and a second transmission line,
wherein the first integrated circuit device includes:
a swing detector configured to detect a voltage level difference between the first transmission line and the second transmission line;
a comparator configured to compare a detection value of the swing detector with a reference swing value; and
a comparison result transmission circuit configured to transmit a comparison result of the comparator to the second integrated circuit device.

2. The system of claim 1, wherein the second integrated circuit device includes:
a differential transmission circuit configured to transmit a differential signal through the first transmission line and the second transmission line; and
a pre-level driving circuit configured to perform pre-level driving to reduce a voltage difference between the first transmission line and the second transmission line, and adjust an intensity of the pre-level driving according to the comparison result transmitted from the first integrated circuit device.

3. The system of claim 2, wherein the swing detector, the comparator and the comparison result transmission circuit of the first integrated circuit device are configured to operate during a training operation.

4. The system of claim 2, wherein the first integrated circuit device further includes:
a reference voltage generator configured to generate a high reference voltage and a low reference voltage; and
a reference swing detector configured to detect a voltage difference between the high reference voltage and the low reference voltage and provide a detection result as the reference swing value.

5. The system of claim 2, wherein the second integrated circuit device further includes a time control circuit configured to adjust a pre-level driving time of the pre-level driving circuit.

6. The system of claim 5, wherein the pre-level driving circuit is configured to be activated for a predetermined time before the differential transmission circuit is activated, and the time control circuit is configured to adjust the predetermined time.

7. The system of claim 2, wherein, when the first integrated circuit device is a memory and the second integrated circuit device is a memory controller, the differential signal is a data clock.

8. The system of claim 1, further comprising a differential receiving circuit configured to receiving the differential signal transmitted through the first transmission line and the second transmission line.

9. An integrated circuit device comprising:
a swing detector configured to detect a voltage level difference between a first transmission line and a second transmission line;
a comparator configured to compare a detection value of the swing detector with a reference swing value; and
a comparison result transmission circuit configured to transmit a comparison result of the comparator.

10. The integrated circuit device of claim 9, further comprising:
a reference voltage generator configured to generate a high reference voltage and a low reference voltage; and
a reference swing detector configured to detect a voltage difference between the high reference voltage and the low reference voltage and provide a detection result as the reference swing value.

11. The integrated circuit device of claim 9, wherein the swing detector includes:
a first analog-to-digital converter configured to convert a voltage level of the first transmission line into a first digital code;
a second analog-to-digital converter configured to convert a voltage level of the second transmission line into a second digital code; and
a subtractor configured to generate the detection value by using a difference between the first digital code and the second digital code.

12. The integrated circuit device of claim 9, wherein the swing detector includes:
a first oscillator configured to generate a first periodic wave corresponding to a voltage level of the first transmission line;
a second oscillator configured to generate a second periodic wave corresponding to a voltage level of the second transmission line;
a first counter configured to count a number of activations of the first periodic wave to generate a first counting value;
a second counter configured to count a number of activations of the second periodic wave to generate a second counting value; and
a subtractor configured to generate the detection value by using a difference between the first counting value and the second counting value.

13. The integrated circuit device of claim 9, further comprising a differential receiving circuit configured to receive a differential signal transmitted through the first transmission line and the second transmission line.

14. The integrated circuit device of claim 9, wherein, when the integrated circuit device is a memory, a data clock is transmitted to the memory through the first transmission line and the second transmission line.

15. The integrated circuit device of claim 14, wherein the swing detector, the comparator and the comparison result transmission circuit are configured to operate during a training operation.

16. An integrated circuit device comprising:
a differential transmission circuit configured to transmit a differential signal through a first transmission line and a second transmission line;
a receiving circuit configured to receive pre-level driving intensity information from a device that receives the differential signal; and
a pre-level driving circuit configured to perform pre-level driving to reduce a voltage difference between the first transmission line and the second transmission line, and adjust an intensity of the pre-level driving according to the pre-level driving intensity information.

17. The integrated circuit device of claim 16, further comprising a time control circuit configured to adjust a pre-level driving time of the pre-level driving circuit.

18. The integrated circuit device of claim 17, wherein the pre-level driving circuit is configured to be activated for a predetermined time before the differential transmission circuit is activated, and the time control circuit is configured to adjust the predetermined time.

19. The integrated circuit device of claim 18, wherein the time control circuit includes:
a plurality of shift circuits configured to shift an activation signal in synchronization with a clock to generate a transmission activation signal of the differential transmission circuit;
a selection circuit configured to select one of former signals of the transmission activation signal from the plurality of shift circuits in response to selection information; and
a signal generation circuit configured to activate a pre-level driving activation signal for activating the pre-level driving circuit in response to a signal selected by the selection circuit, and deactivate the pre-level driving activation signal in response to the transmission activation signal.

20. The integrated circuit device of claim 19, wherein the time control circuit further includes a delay circuit configured to delay the signal selected by the selection circuit, and transmit a delayed signal to the signal generation circuit.

21. The integrated circuit device of claim 16, wherein the pre-level driving circuit includes:
a plurality of pull-up drivers configured to perform pull-up driving on the first transmission line; and
a plurality of pull-down drivers configured to perform pull-down driving on the second transmission line,
wherein a number of activated drivers among the pull-up drivers and the pull-down drivers are determined according to the pre-level driving intensity information.

22. The integrated circuit device of claim 15, wherein, when the integrated circuit device is a memory controller, the differential signal is a data clock.
